(19) United States
(12) Patent Application Publication
(10) Pub. No.: US 2010/0241373 A1
(43) Pub. Date: Sep. 23, 2010

(54) ESD PROTECTION VERIFICATION APPARATUS AND METHOD

(75) Inventor: Kentaro Watanabe, Essex Junction, VT (US)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/715,580

(22) Filed: Mar. 2, 2010

(30) Foreign Application Priority Data
Mar. 18, 2009 (JP) 2009-067011

(51) Int. Cl. G01R 31/02

(52) U.S. Cl. 702/58

(57) ABSTRACT

An ESD protection verification apparatus of an aspect of the present invention including an element extraction unit which extracts one or more elements connected to a first pad included in design data for a semiconductor integrated circuit, a first and second element information checking/processing unit which checks connection information for the extracted element and which calculates a operating value based on design information for the extracted element, a first and second error detection unit which compares a reference value with the operating value to determine whether the element has a predetermined ESD withstand voltage.

### CROSS-REFERENCE TO RELATED APPLICATIONS

This application is based upon and claims the benefit of priority from prior Japanese Patent Application No. 2009-067011, filed Mar. 18, 2009, the entire contents of which are incorporated herein by reference.

### BACKGROUND OF THE INVENTION

1. Field of the Invention

The present invention relates to an ESD protection verification apparatus and an ESD protection verification method.

2. Description of the Related Art

An ESD protection circuit for protecting an internal circuit from electrostatic discharge (ESD) due to an external overcurrent is provided in a semiconductor integrated circuit.

One technique for verifying whether the ESD protection circuit satisfies a required ESD withstand voltage is disclosed in, for example, Jpn. Pat. Appln. KOKAI Publication No. 2006-107250.

In Jpn. Pat. Appln. KOKAI Publication No. 2006-107250, an ESD protection network composed of a pad, a net and an ESD protection element is extracted from design layout data for the semiconductor integrated circuit. Then, a start-point pad and an end-point pad are set for two or more pads provided in the extracted ESD protection network. An inter-pad voltage across the start-point pad and the end-point pad is obtained, and at the same time, a plurality of ESD paths composed of the nets and the ESD protection elements through which to extend between the start-point pad and the end-point pad are obtained. In Jpn. Pat. Appln. KOKAI Publication No. 2006-107250, the ESD current paths are grouped by the correspondence of the order of the nets and the protection elements.

On the basis of the negative correlation between the inter-pad voltage and the ESD withstand voltage for each group, a predictive value of the ESD withstand voltage across the start-point pad and the end-point pad is obtained from the inter-pad voltage across the start-point pad and the end-point pad and from the groups to which the start-point pad and the end-point pad belong. On the basis of this predictive value, whether the ESD protection of the design layout data is proper is determined.

There are a great number of parasitic diodes in a normal semiconductor integrated circuit. If all these parasitic diodes are extracted as ESD paths, a great number of diodes are to be taken into consideration, so that the ESD protection of the design layout data cannot be verified at high speed.

Therefore, in a method used in the step of extracting the ESD protection elements in Jpn. Pat. Appln. KOKAI Publication No. 2006-107250, the diodes arranged as the ESD protection elements in the design layout data for the semiconductor integrated circuit are recognized separately from the parasitic diodes. As with the diodes, in the step of extracting field effect transistors for ESD protection, the field effect transistors for ESD protection are extracted separately from normal field effect transistors that configure logic circuits and analog circuits.

However, there is naturally a possibility that elements other than the ESD protection elements, such as the parasitic diodes, may be ESD paths. For example, a clamp voltage is lower in the parasitic diode than in the ESD protection diode, so that an ESD breakdown current (ESD surge) tends to be supplied to the parasitic diode. If the parasitic diode which may be an ESD path does not have enough performance to discharge the ESD breakdown current, the element and circuit that include the parasitic diode is destroyed by ESD. This leads to the failure of the whole semiconductor integrated circuit that is manufactured by use of the design layout data.

### BRIEF SUMMARY OF THE INVENTION

An ESD protection verification apparatus of an aspect of the present invention comprising: an element extraction unit which extracts one or more elements connected to a first pad included in design data for a semiconductor integrated circuit; a first element information checking/processing unit which checks connection information for the extracted element to determine one or more first connection information elements and which calculates a first operating value based on design information for the first connection information element, the first connection information element being configured so that a first electrode of the extracted element is connected to the first pad; a first error detection unit which compares a first reference value with the first operating value to determine whether the first connection information element has a predetermined ESD withstand voltage; a second element information checking/processing unit which checks connection information for the first connection information element to determine one or more second connection information elements and which calculates a second operating value based on design information for the second connection information element, the second connection information element being configured so that a second electrode of the first connection information element is connected to a second pad different from the first pad; and a second error detection unit which compares a second reference value with the second operating value to determine whether the second connection information element has a predetermined ESD withstand voltage.

An ESD protection verification apparatus of an aspect of the present invention comprising: an element extraction unit which selects one first pad from a plurality of pads included in design data for a semiconductor integrated circuit and extracts an element connected to the selected first pad; an element information examining unit which checks design information for the extracted element; a processing unit which calculates an operating value indicating operating characteristics of the extracted element on the basis of the checked design information; and an error detection unit which compares the operating value with a reference value and determines whether the extracted element has a predetermined ESD withstand voltage.

An ESD protection verification method of an aspect of the present invention comprising: extracting one or more elements connected to a first pad included in design data for a semiconductor integrated circuit; checking connection information for the extracted element to determine one or more first connection information elements, and calculating a first operating value based on design information for the first connection information element, the first connection information element being configured so that a first electrode of the extracted element is connected to the first pad; comparing a first reference value with the first operating value to determine whether the first connection information element has a predetermined ESD withstand voltage; checking connection information for the first connection information element to determine one or more second connection information elements, and calculating a second operating value based on design information for the second connection information element, the second connection information element being configured so that a second electrode of the first connection information element is connected to a second pad different from the first pad; and comparing a second reference value with the second operating value to determine whether the second connection information element has a predetermined ESD withstand voltage.

### BRIEF DESCRIPTION OF THE SEVERAL VIEWS OF THE DRAWING

FIG. 1 is a diagram showing the configuration of an ESD protection verification apparatus according to a first embodiment;

FIG. 2 is a schematic diagram for explaining design layout data;

FIG. 3A is a schematic diagram for explaining the structure of an element to be targeted for verification;

FIG. 3B is a schematic diagram for explaining the structure of an element to be targeted for verification;

FIG. 4 is a flowchart for explaining an ESD protection verification method according to the first embodiment;

FIG. 5 is a schematic diagram for explaining the ESD protection verification method according to the first embodiment;

FIG. 6 is a schematic diagram for explaining a second embodiment;

FIG. 7 is a diagram showing the configuration of an ESD protection verification apparatus according to the second embodiment;

FIG. 8 is a flowchart for explaining an ESD protection verification method according to the second embodiment;

FIG. 9 is a diagram showing the configuration of an ESD protection verification apparatus according to a third embodiment;

FIG. 10 is a flowchart for explaining an ESD protection verification method according to the third embodiment; and

FIG. 11 is a diagram for explaining a modification of the embodiments of the present invention.

### DETAILED DESCRIPTION OF THE INVENTION

Embodiments of the present invention will hereinafter be described in detail with reference to the drawings.

### (1) First Embodiment

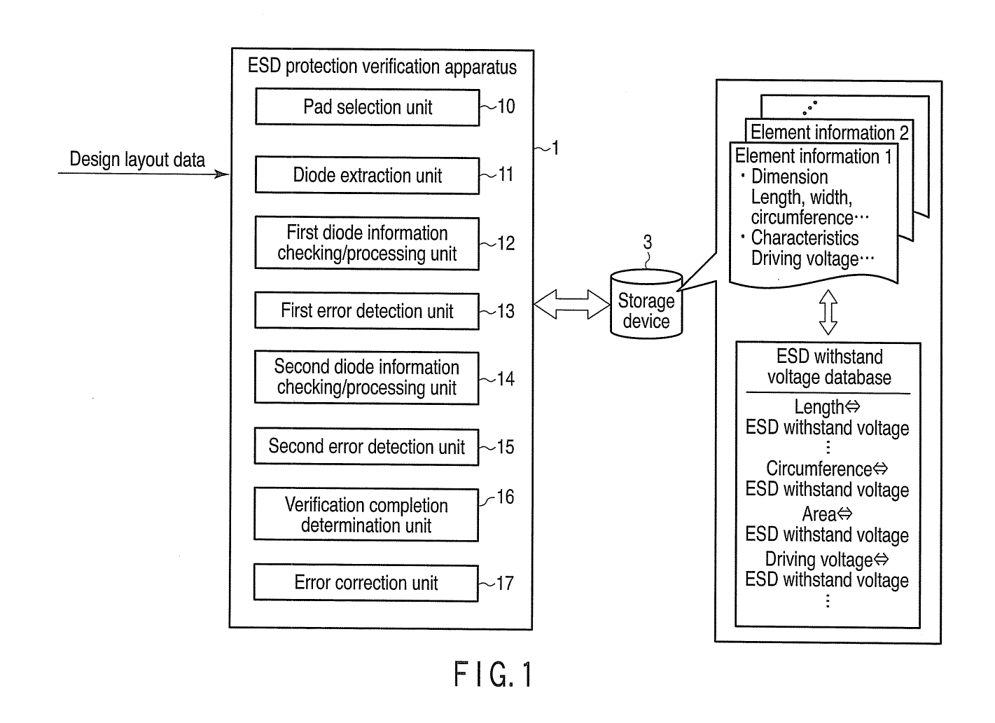

A first embodiment of the present invention is described with reference to FIGS. 1 to 5.

(a) Configuration

An ESD protection verification apparatus according to the first embodiment of the present invention is described with reference to FIGS. 1 to 3B.

FIG. 1 shows en example of the configuration of the ESD protection verification apparatus according to the present embodiment.

Design layout data is input to an ESD protection verification apparatus 1 from the outside. The design layout data includes design information for a certain semiconductor integrated circuit chip. The design information indicates information for constructing a certain semiconductor integrated circuit; for example, the layout of a plurality of circuit blocks constituting the semiconductor integrated circuit, the layout of pads and interconnects, coordinates of elements constituting the semiconductor integrated circuit, dimension and electrical properties of the elements, inter-circuit and inter-element connections, and connections between the pads and the elements (circuits).

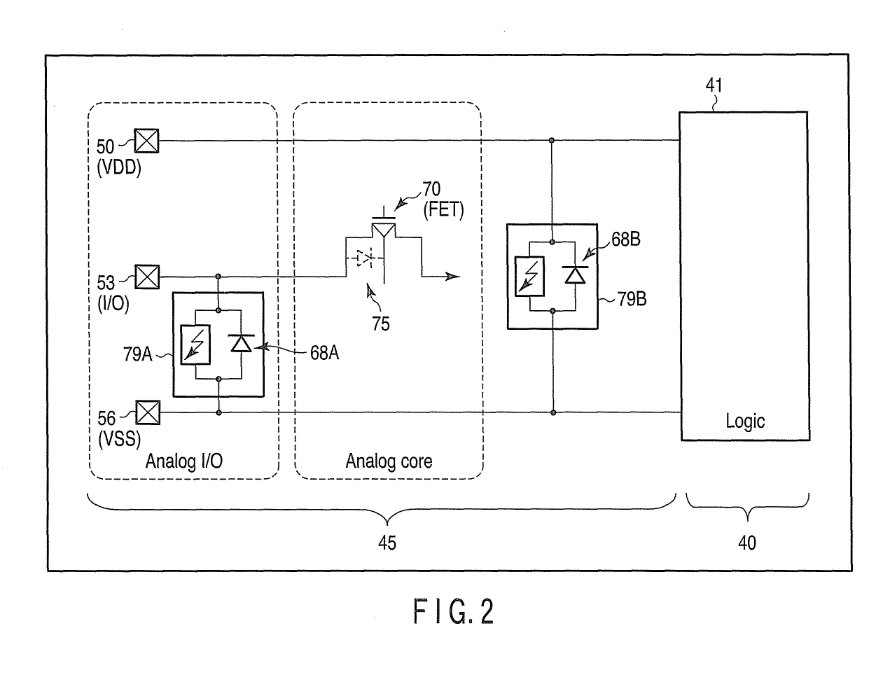

FIG. 2 schematically shows the design information included in the design layout data. As shown in FIG. 2, the design layout data is mainly composed of layout data for a logic circuit region 40 and layout data for an analog circuit region 45. The design layout data may also include layout data (layer) for a mask for forming, for example, a well region to be provided in a semiconductor substrate.

The layout data for the logic circuit region 40 includes layout data for a logic circuit 41 constituted of a plurality of logic gates and for interconnects connecting the logic gates.

The layout data for the analog circuit region 45 includes layout data for a pad 53 for inputting/outputting data to/from the logic circuit region 40 and pads 50, 56 for supplying a voltage to the chip. The data for the analog circuit region 45 also includes layout data for analog circuits 70, 79A, 79B provided between the pads 50, 53, 56 and the logic circuit 40 and for interconnects thereof. The analog circuits 79A, 79B correspond to, for example, ESD protection circuits 79A, 79B and a switch circuit 70.

The ESD protection verification apparatus 1 uses, for example, a database stored in a storage device 3 to verify whether ESD protection of the design layout data is proper.

The storage device 3 stores data for constituent elements of the semiconductor integrated circuit included in the design layout data. The data for the constituent elements will hereinafter be referred to as element information data. The element information data includes information on the dimension and operating characteristics of the elements; for example, the length, width and circumference of the diode, the gate length and gate width of a metal-oxide-insulator (MOS) field effect transistor (FET), and a driving voltage.

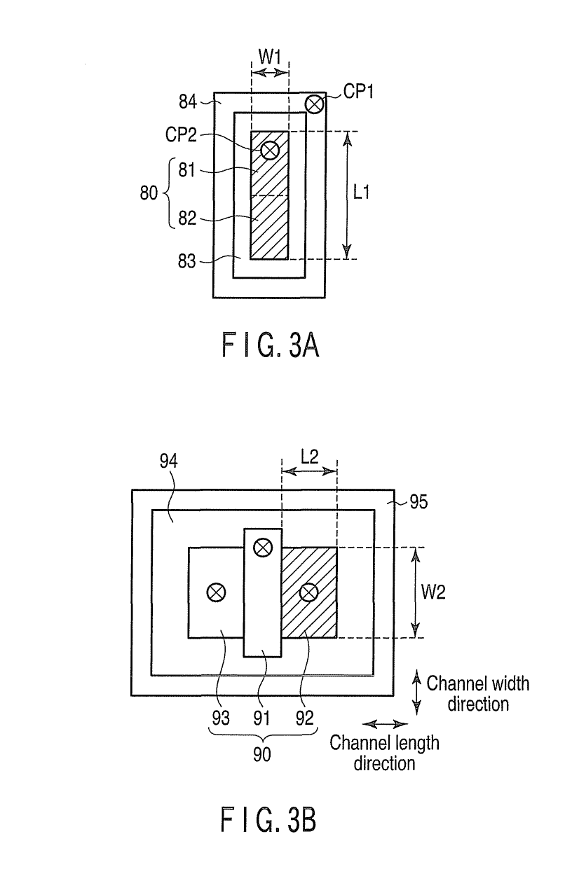

For example, as shown in FIG. 3A, an element isolation region 83 is provided in a semiconductor region (well region) 84. Further, a diode 80 is provided in an active region surrounded by the element isolation region 83. Diode 80 is composed of a P-type impurity region 81 and an N-type impurity region 82. For example, the element information data for diode 80 includes at least one of the following pieces of information: length L1 of diode 80, width W1 of diode 80, the area (L1×W1) of diode 80, and the circumference (2×L1+2×W1) of diode 80. The element information data for the diode may also include, as element information, the impurity concentrations in the impurity regions 81, 82 and the semiconductor region 84 constituting diode 80, the numbers of contact plugs CP1, CP2 connected to diode 80, and electrical properties of, for example, the clamp voltage of the diode.

Furthermore, as shown in FIG. 3B, an element isolation region 94 is provided in a semiconductor region (well region) 95, and a metal-oxide-insulator (MOS) transistor 90 is provided in an active region surrounded by the element isolation region 94. The MOS transistor 90 is composed of two impurity regions 92, 93 serving as a source and a drain, and a gate 91 provided on a channel region between the source 92 and the drain 93 via a gate insulating film.

The element information for the MOS transistor 90 includes at least one of the following pieces of information: dimension L2 of the source/drain 92, 93 in a channel length direction, dimension W2 in a channel width direction, the area (L1×W1) of one of the source/drain 92, 93, and the circumference (2×L1+2×W1) of one of the source/drain 92, 93. The element information for the MOS transistor 90 may also include, for example, information on the gate length and gate width of the gate 91, the impurity concentrations in the source/drain 92, 93, materials constituting the gate insulating film and the gate, the number of contact plugs connected to the gate 91 and the source/drain 92, 93, the impurity concentrations in the semiconductor region 95, and operating characteristics (e.g., a threshold voltage) of the MOS transistor.

Furthermore, a database (hereinafter referred to as an ESD withstand voltage database) regarding ESD withstand voltages is stored in the storage device 3. The ESD withstand voltage of the element is correlated with the dimension and operating characteristics of the element. For example, if the circumference or area of an element is greater, the density of a current running through the element can be lower, so that the ESD withstand voltage is greater. That is, if the area or circumference of an element is found, the ESD withstand voltage of the element can be found.

In addition, information on the ESD withstand voltage of the element may be included in the element information data. The element information data and the ESD withstand voltage database may be provided to the ESD protection verification apparatus 1 by an internal storage device, a communication line or a storage medium provided in the ESD protection verification apparatus 1.

The ESD protection verification apparatus 1 according to the present embodiment has a pad selection unit 10 for selecting one pad from the layout data for a plurality of pads 50, 53, 56 in the design layout data. The pad selected by the pad selection unit 10 (hereinafter referred to as a selected pad) is treated as a base point of a target for the verification of the ESD withstand voltage. The target to be mainly selected by the pad selection unit 10 is, for example, a signal or data input/output pad. However, without being limited thereto, the target to be selected by the pad selection unit 10 may be, for example, a power supply pad.

Furthermore, the ESD protection verification apparatus 1 according to the present embodiment has a first element extraction unit 11 for extracting layout data for an element connected to the selected pad among a plurality of elements included in the design layout data. In the first embodiment, the element extracted by the element extraction unit 11 is a diode. In the first embodiment, the element extraction unit 11 will hereinafter be referred to as a diode extraction unit 11.

The diode extraction unit 11 extracts diodes (ESD protection diodes) 68A, 68B as ESD protection elements provided in the ESD protection circuits 79A, 79B in FIG. 2. The diode extraction unit 11 not only extracts diodes 68A, 68B but also extracts a normal diode and a parasitic diode 75 directly connected to the same selected pad as diodes 68A, 68B. The parasitic diode 75 is, for example, a PN junction included in the analog circuit 70. On the basis of the input design layout data, the diode extraction unit 11 equivalently determines, as a diode, a MOS transistor including a junction between the source (drain) and the substrate or determines, as a diode, the border between the P-type impurity region (e.g., a P-type well region) and the N-type impurity region (e.g., an N-type well region), thereby extracting a parasitic diode. In addition, the normal diode means a diode used to configure a certain circuit.

Thus, the diode extraction unit 11 provided in the apparatus 1 according to the present embodiment not only extracts, as a discharge path (hereinafter referred to as an ESD path) for an ESD breakdown current and an ESD surge, the diode serving as the ESD protection element, but also extracts the normal diode and the parasitic diode connected to the selected pad as diodes that may be ESD paths.

It goes without saying that the element extraction unit 11 may have a function of extracting the MOS transistor instead of the diode.

The ESD protection verification apparatus 1 has a first diode information checking/processing unit (first element information calculation unit) 12. The diode information checking/processing unit 12 uses the design layout data and the data stored in the storage device to check connection information for one or more diodes extracted by the diode extraction unit 11, and determines a diode having the same connection information regarding the selected pad. Then, the diode information checking/processing unit 12 processes the dimension of the diode having the same connection information regarding the selected pad among the extracted diodes. In the present embodiment, information on the connection of one end of the current path of the element to the selected pad is referred to as first connection information. For example, if the element is a diode, information indicating the connection between the anode and the selected pad is referred to as the first connection information. Further, the element having one end of its current path connected to the selected pad (first pad), that is, the element having the first connection information is referred to as a first connection information element. For example, if the element is a diode, the element having its anode connected to the selected pad is the first connection information element.

In this example, the first diode information checking/processing unit 12 checks the connection information for the anode of the extracted diode, and calculates an operating value (first operating value) on the basis of the dimension of the diode (first connection information element) having its anode connected to the same selected pad. Consequently, the dimension of the diode having its cathode connected to the selected pad is not included in the operating value.

If there are two or more diodes having their anodes connected to one selected pad, the diode information checking/processing unit 12 calculates the sum of the dimensions of these diodes. If there is one diode having its anode connected to the selected pad, the diode information checking/processing unit 12 outputs the dimension of the one diode as an operating value. Here, the dimension of the diode to be found is at least one of the area (L1×W1), width W2, length L1 and circumference (L1+W1) of the diode. In addition, the diode information checking/processing unit 12 may acquire the dimension of the element on the basis of information (e.g., element numbers) added to the design layout data or may acquire the dimension of the element directly from the layout of the elements in the design layout data.

The diode information checking/processing unit 12 outputs, as an operating value for use in a subsequent processing step, the sum of the dimensions of the elements having the same connection information. In addition, the operating value may be indicated by the sum of the dimensions of the elements or may be indicated by the value of the ESD withstand voltage obtained from the ESD withstand voltage database on the basis of the sum.

Although the operating value is calculated from the dimension of the element in this example, the operating value may be calculated from a value (score) converted from the operating characteristics or electrical properties of the element. Moreover, although the first diode information checking/processing unit 12 checks and processes the connection information for the anode in this example, it goes without saying that the same checking and processing may also be performed for the cathode.

A first error detection unit 13 uses the database in the storage device 3 to compare a reference value (first reference value) with the first operating value obtained by the diode information checking/processing unit 12.

The reference value used by the error detection unit 13 is, for example, a value predicted from the ESD breakdown current or the ESD surge caused in a pad, and is set by the error detection unit 13 in the following manner: data based on the result of a previously conducted experiment or simulation is acquired from the storage device 3, or the error detection unit 13 finds a value through a simulation from the information for the selected pad.

If easily compared with the operating value, the reference value may be indicated by a value based on the ESD withstand voltage predicted from the ESD breakdown current or the ESD surge caused in the pad or may be indicated by a value based on a dimension (e.g., the circumference or area) correlated with the ESD withstand voltage.

If the error detection unit 13 determines that the calculated operating value is greater than or equal to the reference value, the diode is regarded as satisfying the required ESD withstand voltage and determined as a diode free of ESD breakdown.

On the other hand, if the first error detection unit 13 determines that the calculated operating value is less than the reference value, the error detection unit 13 considers that ESD breakdown may be caused in this diode, and detects this element as a design error. The error detection unit 13 saves positional information in the layout data regarding the element extracted as the error in, for example, the storage device 3 or in the storage device in the apparatus 1. Moreover, the error detection unit 13 may directly reflect, in the design layout data, the positional information for the element extracted as the error to mark this element.

Thus, using the connection information for the anode of the extracted diode, the first diode information checking/processing unit 12 and the first error detection unit 13 perform ESD protection verification for the element (diode) having the same connection information regarding the pad.

A second diode information checking/processing unit (second element information checking/processing unit) 14 checks connection information (second connection information) for an electrode of the diode (first connection information element) used to calculate the operating value different from the electrode connected to the selected pad, here, the cathode of the diode, and determines a diode (second connection information element) having the same connection information.

In the present embodiment, the connection information for the other electrode of the current path of the first connection information element is referred to as second connection information. For example, if the element is a diode, information indicating the connection between the cathode and the pad is referred to as the second connection information. Moreover, in the present embodiment, an element having one end of its current path connected to the selected pad and having the other end thereof connected to another pad, that is, an element having the second connection information is referred to as a second connection information element. For example, if the element is a diode, an element having its anode connected to the selected pad and having its cathode connected to another pad is the second connection information element.

Furthermore, as with the diode information checking/processing unit 12, the diode information checking/processing unit 14 uses at least one of the length, width, circumference and area to calculate an operating value (second operating value) based on the dimension of the diode having its cathode connected to the same pad.

However, it goes without saying that even the diodes having their anodes connected to the same selected pad may have their cathodes connected to different pads. Thus, the diode information checking/processing unit 14 uses, as one unit, one or more diodes having the cathodes connected to the same pad among a plurality of diodes having their anodes connected to the same pad, so that the diode information checking/processing unit 14 calculates an operating value based on the dimensions of these diodes using, as a unit, the pads to which the cathodes are connected.

In addition, the diodes targeted by the diode information checking/processing unit 14 for a check of the connection conditions of the cathodes and for the calculation of the operating value may include diodes determined as errors by the error detection unit 13 or may not include the diodes determined as errors.

As with the first error detection unit 13, a second error detection unit 15 uses the database in the storage device 3 to compare the operating values of one or more diodes having their cathodes connected to the same pad with a reference value (second reference value). The second error detection unit 15 performs, for the diodes having their cathodes connected to the same pad and having their anodes connected to the selected pad, processing substantially similar to the processing which is performed for the diodes having their anodes connected to the same pad.

However, as described above, in contrast with the anodes of the extracted diodes connected to one common pad (selected pad), the cathodes of the extracted diodes may be connected to different pads. Therefore, using, as one unit, one or more diodes having their cathodes connected to the same pad among one or more diodes which are extracted by the diode extraction unit 11 and which have their anodes connected to one selected pad, the second error detection unit 15 independently compares the second operating values with the reference value using, as a unit, the pads to which the cathodes are connected.

As a result, if the calculated operating value is less than the reference value, one or more diodes having the same connection information regarding the pad used to calculate the operating value is regarded as not ensuring the ESD withstand voltage and detected as an error.

In addition, the reference value used by the second error detection unit 15 is, for example, a value predicted from ESD breakdown currents or ESD surges caused in the selected pad and in a pad to which the cathodes are connected, and is set by acquiring data from the storage device 3 or by finding a value through a simulation from the information for two pads, in the same manner as the reference value used by the first error detection unit 13.

Thus, using the connection information for the cathode of the extracted diode, the second diode information checking/processing unit 14 and the second error detection unit 15 perform ESD protection verification.

Then, a verification completion determination unit 16 in the ESD protection verification apparatus 1 determines whether the verifications for all the pads included in the design layout data are complete. If the verifications for all the pads are not complete, pads which are not targeted for verification are selected by the pad selection unit 10, and processing by the diode information checking/processing unit 12, 14 and the error detection units 13, 15 are performed in the same manner as described above.

When the verification completion determination unit 16 determines that the verifications for all the pads are complete, an error correction unit 17 provided in the ESD protection verification apparatus 1, for example, corrects data on the dimension and characteristics included in the design layout data, such as the areas and circumferences of the ESD protection diodes and the parasitic diode detected as errors. Moreover, for the ESD protection diodes and the normal diode, data on the element evaluated as an error may be replaced with data on the element satisfying the ESD withstand voltage. In addition, instead of correcting the dimension of the element, the design layout data may be changed to newly provide an ESD protection diode for the error element.

The error correction unit 17 may be provided in an apparatus (e.g., a design layout data creating apparatus) different from the ESD protection verification apparatus 1. This prevents a semiconductor integrated circuit manufactured in accordance with the design layout data from being destroyed by ESD.

As described above, the ESD protection verification apparatus 1 according to the first embodiment extracts one or more diodes connected to a certain pad, and calculates dimensions of the anode and the cathode of this diode. Then, on the basis of the result of the calculation, the ESD protection verification apparatus 1 determines whether the extracted diodes meet a predetermined standard. Consequently, in the design layout data, whether the diodes which can be ESD paths satisfy the required ESD withstand voltage is verified.

The ESD protection verification apparatus 1 in the present embodiment not only extracts the diodes provided for ESD protection but also extracts the normal diode and the parasitic diode present in the current path that can be ESD paths.

Then, taking advantage of the fact that the ESD withstand voltage and the dimension of an element have a correlation, the ESD protection verification apparatus 1 calculates an operating value based on the dimensions of all the diodes present on the ESD path, and determines whether the ESD protection diode and the parasitic diode satisfy the ESD withstand voltage.

Thus, the ESD protection verification apparatus 1 according to the first embodiment not only extracts the diodes for ESD protection but also extracts the parasitic diode connected to the pad, and performs a verification for protection against ESD in consideration of the ESD withstand voltage of this parasitic diode.

The ESD protection verification apparatus 1 in the present embodiment not only verifies the ESD withstand voltage of the ESD protection circuit but also verifies the ESD withstand voltage of the parasitic diode included in a circuit other than the ESD protection circuit. If the ESD withstand voltage of the parasitic diode is not ensured, a part (e.g., the border between the P-/N-type wells) of the layout data corresponding to the parasitic diode is detected as a target for correction. This makes is possible to prevent the ESD breakdown of a circuit which is not determined to be an ESD protection circuit and which includes a parasitic diode that may be an ESD path. That is, the reliability of the ESD protection verification improves.

Furthermore, when extracting a parasitic diode, the ESD protection verification apparatus 1 in the present embodiment extracts a parasitic diode connected to a pad targeted for verification, and does not include, in the ESD protection verification, parasitic diodes which are not connected to this pad. That is, instead of considering all the parasitic diodes present in the design layout data, the ESD protection verification apparatus 1 selectively extracts parasitic diodes that are likely to be ESD paths without any drop in the ESD breakdown current or ESD surge attributed to other elements. Thus, even if the parasitic diodes are included in the target for the ESD protection verification, there is no significant deterioration in the speed of the ESD protection verification for the design layout data.

Moreover, in the present embodiment, the ESD withstand voltage of the parasitic diode is also treated as an ESD withstand voltage included in a network that can be an ESD path. As a result, an ESD withstand voltage higher than the ESD withstand voltage designed for a certain network by using the ESD protection circuit may be obtained. A value including the ESD withstand voltage of the parasitic diode can be reflected in the design layout data to reduce the dimensions of the ESD protection diode. This makes it possible to contribute to the reduction of chip size.

As described above, according to the ESD protection verification apparatus 1 in the first embodiment, highly reliable ESD protection verification can be performed at high speed.

Although the diode has been described as an example of the element targeted for the ESD protection verification in the present embodiment, it goes without saying that the element may be a MOS transistor or a resistive element.

(b) Operation

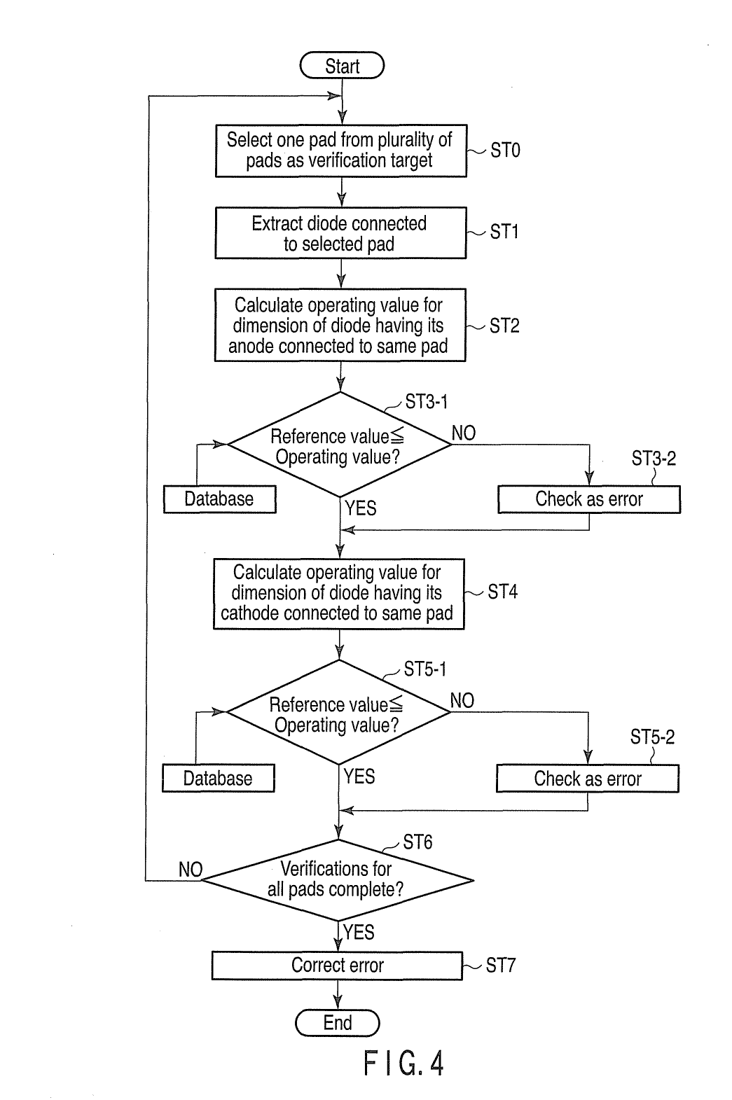

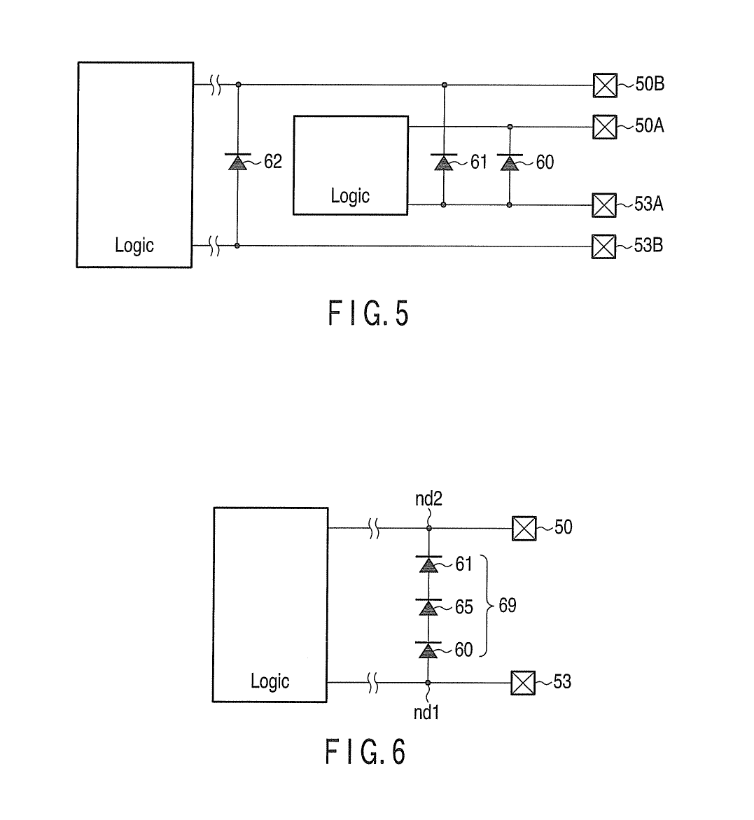

The operation of the ESD protection verification apparatus 1 according to the first embodiment of the present invention is described with reference to FIGS. 4 and 5. In addition, FIGS. 1 to 3 are also referred to here for explanation as needed.

FIG. 4 is a flowchart showing a processing flow of the ESD protection verification method according to the first embodiment of the present invention. FIG. 5 shows one example of a circuit to be targeted for verification for explaining the ESD protection verification method of the first embodiment.

First, design layout data for a semiconductor integrated circuit is input to the ESD protection verification apparatus 1, and ESD protection verification for this design layout data is started.

Then, as shown in FIG. 4, among a plurality of pads included in the input design layout data, one pad (first pad) is selected by the pad selection unit 10 in the ESD protection verification apparatus 1 in FIG. 1 (step ST0). The selected pad is set as a base point of a target for the ESD protection verification. In this example, a pad 53A shown in FIG. 5 is the pad selected in step ST0, and the pad 53A will hereinafter be referred to as a selected pad 53A. In step ST0, the pad to be selected is, for example, a signal or data input/output pad, but needless to say, may be a power supply pad instead.

Furthermore, in step ST1 in FIG. 4, an element connected to the selected pad 53A in the design layout data is extracted by the first diode extraction unit (first element extraction unit) 11 in the apparatus 1. It is to be noted that the element to be extracted is a diode in this example. However, it goes without saying that the element to be extracted may be a MOS transistor.

Thus, one or more diodes connected to selected pad 53A are extracted as in step ST1. In the example shown in FIG. 5, two diodes 60, 61 are selected. A diode 62 is connected to a pad 53B and a pad 50B and is therefore not extracted.

In step ST1, the diodes to be extracted not only include, for example, diodes 68A, 68B as the ESD protection elements provided in the ESD protection circuits 79A, 79B shown in FIG. 2 but also include the parasitic diode 75 connected to the selected pad 53A. The parasitic diode is extracted by, for example, equivalently determining, as a diode, a field effect transistor connected to a pad on the basis of information in the input design layout data or by determining, as a diode, the border between the P-type impurity region (e.g., a P-type well region) and the N-type impurity region (e.g., an N-type well region). It goes without saying that not only the ESD protection diode and the parasitic diode but also a normal diode for configuring the analog circuit may be extracted.

In addition, no diode may be connected to the selected pad. If there is no diode connected to the selected pad, another pad is selected as a pad targeted for verification.

Then, connection information for one or more extracted diodes is checked by the first diode information checking/processing unit 12 in the apparatus 1. Among the extracted diodes, a diode having its anode connected to the selected pad is recognized. Further, the sum of the dimensions of two or more diodes having their anodes connected to the selected pad is calculated by the first diode information checking/processing unit 12 in the apparatus 1, and output as an operating value (first operating value) (step ST2). In addition, if one diode is extracted in step ST1, the dimension (e.g., the area) of one diode is processed as the operating value in step ST2. In this step, a diode having its cathode connected to the selected pad 53A is not included in the target for calculation.

In step ST2, the values treated as the dimensions are, to explain with reference to FIG. 3A, the area (W1×L1) of diode 80, the circumference (2×W1+2×L1) of diode 80, width W1 and length L1. One of these values may be selected to find the operating value (the sum of the dimensions of the diodes), or two or more of these values may be properly combined together to find the operating value. Thus, a value based on the total value of the dimensions of diodes 60, 61 shown in FIG. 5 is calculated as the operating value.

A database (ESD withstand voltage database) indicating the correlation between the operating value based on the dimensions of the diodes and the ESD withstand voltage is obtained by a previously conducted simulation or experiment. This database is stored in, for example, the storage device 3. Without limiting to the dimensions of the diodes, the database may indicate the correlation between operating characteristics such as an operating voltage of the diode and the ESD withstand voltage.

If a diode having its cathode connected to the selected pad instead of its anode is extracted in step 1, an operating value of the diode having its cathode connected to the selected pad may be calculated in step 2.

Then, whether the calculated operating value is greater than or equal to a certain reference value (first reference value) is determined by the first error detection unit 13 using the database stored in the storage device 3 (step ST3-1).

The reference value used by the error detection unit 13 is, for example, a value predicted from an ESD breakdown current or ESD surge caused in the pad. This reference value is set by the error detection unit 13 in the following manner: data based on the result of a previously conducted experiment or simulation is acquired from the storage device 3, or the error detection unit 13 finds a value through a simulation from the information for the selected pad. If the operating value is the area of the diode, the reference value is set at a value indicating the correlation between the area and the ESD withstand voltage.

The ESD breakdown current or ESD surge applied to one pad is divided to the elements connected to this common pad. Therefore, even if the operating value based on one diode is less than the reference value, there is a strong possibility that the ESD withstand voltage is satisfied if an operating value based on the dimensions of a plurality of diodes having the same connection information regarding the same selected pad is greater than or equal to the reference value. Thus, these diodes are not determined as elements that cause the ESD breakdown.

Therefore, if the operating value is determined to be greater than or equal to the reference value, the diode is regarded as ensuring a predetermined ESD withstand voltage, and determined and processed as an element requiring no correction.

If the operating value is determined to be less than the reference value, the diode is regarded as an error element that may cause ESD breakdown. Then, for example, positional information (coordinates) for the diode (error element) from which the operating value is obtained is saved in a storage device inside or outside the apparatus 1, or error marks are added to such diodes in the design layout data (step ST3-2). Thus, the error element is targeted for correction as an element that needs to be redesigned.

As described above, in steps ST3-1 and ST3-2, whether one or more diodes (first connection information elements) in which the anodes have the same connection information (first connection information) regarding the selected pad ensure the predetermined ESD withstand voltage is verified by the first diode information checking/processing unit 12 and the first error detection unit 13 using the connection information for the anode of the extracted diode.

Subsequently, the connection information for the cathodes of the elements (first connection information elements) used to calculate the operating value is checked by the second diode information checking/processing unit (second element information checking/processing unit) 14. Then, the sum of the dimensions of one or more diodes having their cathodes connected to the same pad is calculated, and output as an operating value (second operating value) (step ST4).

As with the operating values calculated in step ST3, the second operating values calculated in step ST4 are, for example, the area (W1×L1) of diode 80, the circumference (2×W1+2×L1) of diode 80, width W1 and length L1.

Here, as shown in FIG. 5, the cathodes of the two diodes 60, 61 having their anodes connected to the same pad 53A are connected to different pads 50A, 50B, respectively.

In this case, an operating value based on the dimension of diode 60 and an operating value based on the dimension of diode 61 are separately calculated.

Furthermore, the cathode of diode 62 is connected to the same pad as the cathode of diode 61. However, in step ST5, the calculated operating values are values targeted at diodes 60, 61 having their anodes connected to the selected pad 53A. Thus, diode 62 is excluded from the target for the calculation of the operating values in step ST5. Therefore, diode 62 has no effect on the calculation of the operating values of diodes 60, 61.

Then, whether the operating values of diodes 60, 61 based on the connection information for the cathodes are greater than or equal to a certain reference value is determined by the second error detection unit 15 using the database stored in the storage device 3 (step ST5-1).

As in steps ST3-1 and ST3-2, diodes whose operating values are determined to be less than the reference value (second reference value) are processed as error elements (step ST5-2). If the operating value is determined to be greater than or equal to the reference value, the diode is regarded as ensuring a predetermined ESD withstand voltage, and processed as an element requiring no correction.

It goes without saying that the reference value (second reference value) corresponding to the connection information (second connection information) for the cathodes used in step ST5-1 may be a different value (size) from or the same value as the reference value (first reference value) corresponding to the connection information (first connection information) for the anodes used in step ST3-1.

As described in step ST4, even the diodes having their anodes connected to the same pad (selected pad) may have their cathodes connected to different pads. Among one or more extracted diodes having their anodes connected to the selected pad, one or more diodes having their cathodes connected to the same pad are treated as one group, and the operating value of this group is compared with the reference value to find out whether this operating value is greater than or equal to the reference value.

In the example shown in FIG. 5, if the operating value for the dimension based on diode 60 connected to the pad 50A is less than the reference value, diode 60 is treated as an error. On the other hand, the cathode of diode 61 is connected to the pad 50B different from the pad to which the cathode of diode 60 is connected. That is, diode 61 is present in an ESD path different from the ESD path where diode 60 is present. That is, the operating value based on the dimension of diode 61 and the operating value based on the dimension of diode 60 are different and determined separately. Therefore, even if the anode is connected to the same pad (selected pad) as the anode of diode 60, diode 61 is determined as requiring no correction for the ESD withstand voltage as long as the operating value for the dimension of this diode 61 calculated in accordance with the connection information of the cathode is greater than or equal to the reference value. In addition, the reference value for diode 60 may be different or the same as the reference value for diode 61.

In steps ST4-1 and ST4-2, whether one or more diodes in which the cathodes have the same connection information regarding a certain pad ensure an ESD withstand voltage greater than or equal to the predetermined ESD withstand voltage is verified using the connection information for the cathodes of extracted diodes among one or more diodes extracted and verified by the first diode information checking/processing unit 12 and the first error detection unit 13.

Thus, in the present embodiment, ESD paths are inspected in the extracted diodes on the basis of the connection information for the anodes of the diodes and the connection information for the cathodes of the diodes. Then, whether the ESD protection diodes and the parasitic diodes present in the ESD path satisfy the required ESD withstand voltage is determined.

After the processing of steps ST1 to ST5-2 has been performed for the pad selected in step ST0, whether the processing for all the pads included in the design layout data is complete is determined (step ST6).

If the verifications for all the pads are not complete, the unverified pads are selected, and the verifications of steps ST0 to ST5-2 are repeated.

When it is determined that the verifications for all the pads are complete, data indicating dimensions such as the area or circumference of diodes determined to be errors is corrected by the error correction unit 17 in the ESD protection verification apparatus 1.

The ESD protection verification of the design layout data is completed by steps ST0 to ST7.

As described above, an ESD protection verification method according to the first embodiment of the present invention targets, for the ESD protection verification, not only the diodes which are included in the design layout data and which are designed for ESD protection but also the parasitic diodes included in parts that may be ESD paths.

However, in the present embodiment, the parasitic diode directly connected to the selected pad is extracted, and the parasitic diode which is not connected to the pad is not included in the ESD protection verification. That is, instead of considering all the parasitic diodes present in the design layout data, parasitic diodes that are likely to be ESD paths without any drop in the ESD breakdown current or ESD surge attributed to other elements are selectively extracted.

As a result, even if the parasitic diodes are targeted for the ESD protection verification, there is no significant deterioration in the speed of the ESD protection verification for the design layout data.

Furthermore, in the present embodiment, not only the ESD withstand voltage of the ESD protection circuit but also the ESD withstand voltage of the parasitic diode included in a circuit other than the ESD protection circuit is verified. If the ESD withstand voltage of the parasitic diode is not ensured, data on the element including the parasitic diode is corrected. This makes is possible to prevent the circuit including the parasitic diode from being destroyed by ESD. Thus, not only the ESD withstand voltage of the ESD protection circuit but also the ESD withstand voltage of the parasitic diode that may be an ESD path is considered, so that the reliability of the ESD protection verification improves.

As described above, according to the ESD protection verification method in the first embodiment, highly reliable ESD protection verification can be performed at high speed.

### (2) Second Embodiment

An ESD protection verification apparatus and an ESD protection verification method according to a second embodiment of the present invention are described using FIGS. 6 to 8. The configuration and operation steps similar to the configuration and operation steps in the first embodiment are described as needed.

One diode is connected between two pads in the example described in the first embodiment. However, as shown in FIG. 6, a plurality of diodes 60, 61, 65 may be connected in series between two pads 50, 53. The plurality of diodes connected in series will hereinafter be referred to as a diode string 69.

There is naturally a case where this diode string 69 serves as an ESD path and is destroyed if ESD occurs.

The apparatus and method described in the second embodiment of the present invention extract the diode string 69 in design layout data, and verify the ESD withstand voltage of the extracted diode string 69.

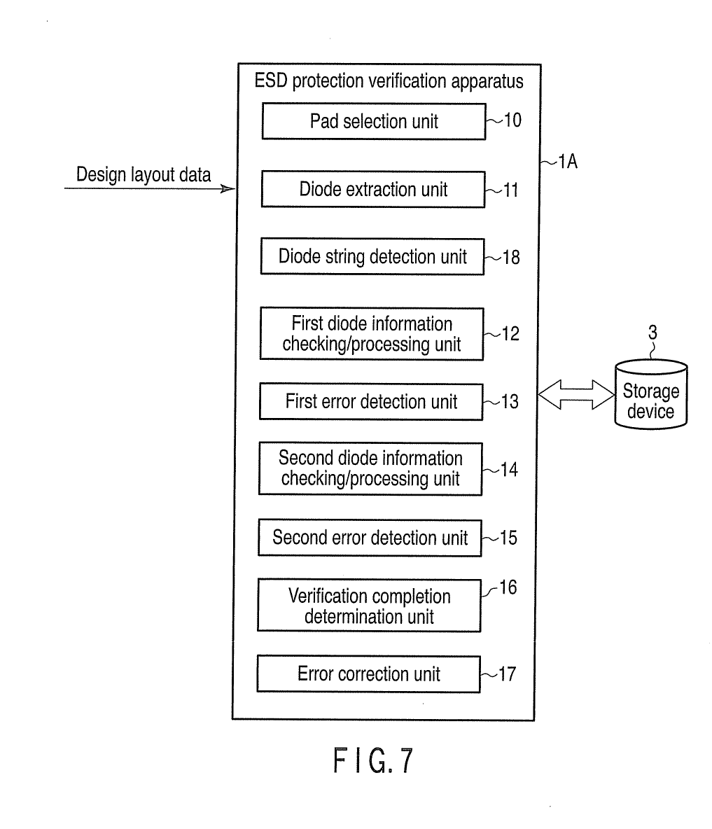

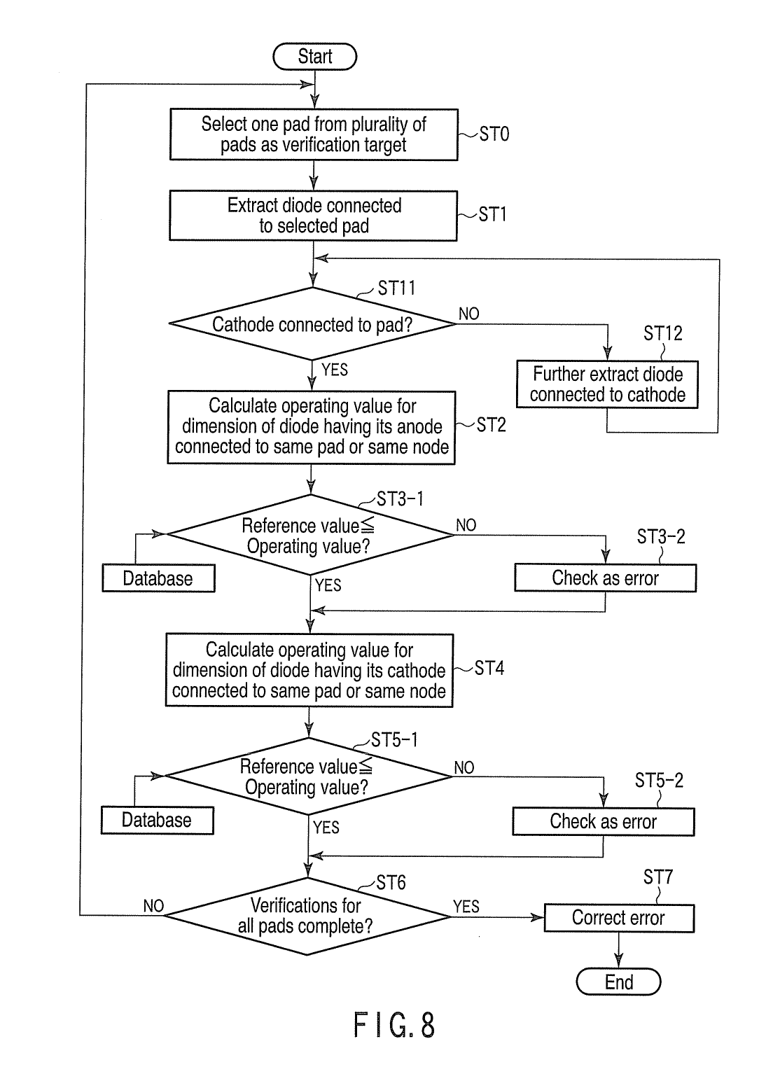

FIG. 7 shows an example of the configuration of an ESD protection verification apparatus 1A according to the present embodiment. FIG. 8 is a flowchart showing a processing flow of the ESD protection verification method according to the present embodiment.

The apparatus 1A shown in FIG. 7 comprises a diode string detection unit (element group detection unit) 17 in addition to the configuration of the apparatus shown in FIG. 1.

As in the first embodiment, a diode extraction unit 11 extracts diodes connected to a selected pad (step ST1).

Then, as shown in FIG. 8, the diode string detection unit 18 checks the extracted diode 60 to find out whether its electrode (here, cathode) which is not connected to the selected pad is connected to another pad (step ST11).

When diode 60 whose cathode is not connected to the pad is detected, the diode string detection unit 18 recognizes that diode 60 is an element which forms the diode string 69. Then, diode 65 connected to the cathode of the diode having its anode connected to the pad is detected. The diode string detection unit 18 further checks the detected diode 65 to find out whether its electrode which is not connected to the cathode of diode 60 is connected to the pad, and detects another diode (step ST12).

The processing of steps ST11 and ST12 is repeated until it is detected that the cathode of the detected diode is connected to the pad.

Furthermore, the processing substantially similar to the processing in ST2 to ST7 performed for the diode in the first embodiment is performed for the extracted diode string and diodes. Thus, an operating value based on the sum of the dimensions of the diode string 69, that is, diodes 60, 61, 65 is calculated, and the ESD withstand voltages of the diode string 69 and diodes 60, 61, 65 are verified.

Among diodes 60, 61, 65 that constitute the diode string 69, diode 65 between diodes 60, 61 at one end of the diode string and the other is connected to the pad via nodes nd1, nd2. Thus, in steps ST3 and ST5, the operating value based on the dimension of the diode string 69 is calculated for the plurality of diodes 60, 61, 65 (the diode string 69) in which the anode side and cathode side of the diode string 69 are connected to the same node. However, the operation of calculating the operating value is substantially the same regardless of whether the anode/cathode is connected to the pad or node.

As described above, the ESD protection apparatus 1A and the ESD protection verification method according to the second embodiment of the present invention can extract a diode connected to the selected pad and the diode string that may be an ESD path.

Furthermore, as in the first embodiment, not only for the diode connected to the selected pad but also for the plurality of extracted diodes constituting the diode string, operating values based on their dimensions are calculated, and the operating values are determined to find out whether a predetermined ESD withstand voltage is satisfied, such that a correction can be made to prevent the occurrence of ESD breakdown.

Consequently, according to the ESD protection verification apparatus 1A and the ESD protection verification method in the second embodiment of the present invention, highly reliable ESD protection verification can be performed at high speed.

### (3) Third Embodiment

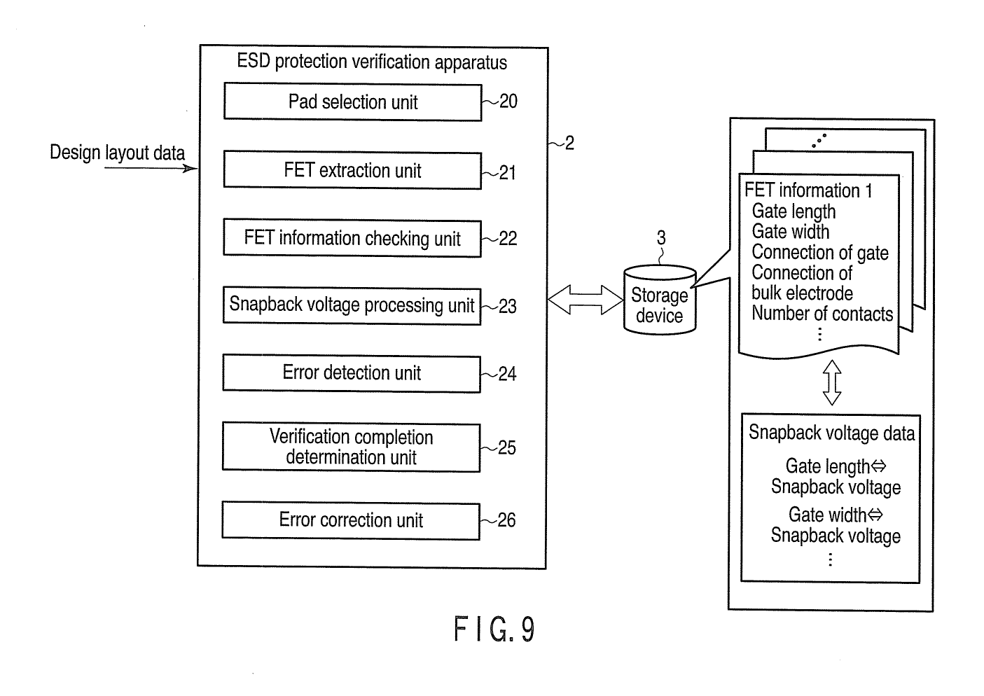

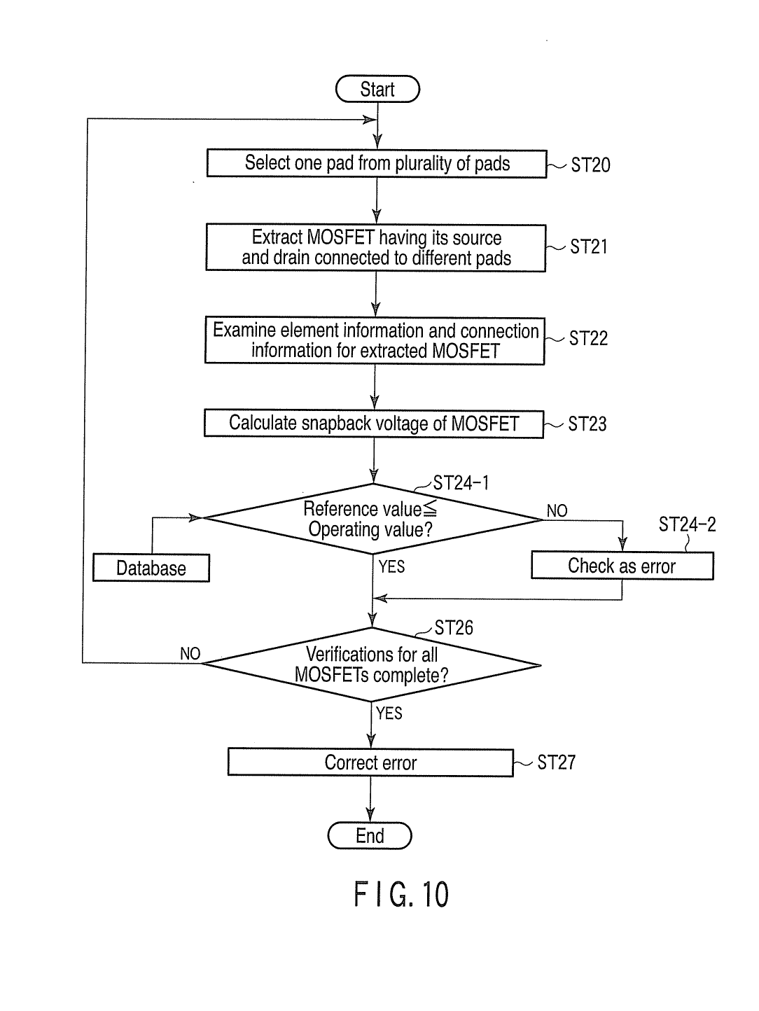

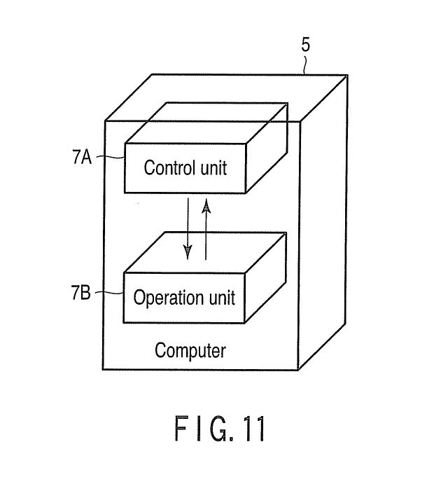

An ESD protection verification apparatus and an ESD protection verification method according to a third embodiment of the present invention are described with reference to FIGS. 9 and 10.

(a) Configuration

The configuration of the ESD protection verification apparatus according to the third embodiment of the present invention is described using FIG. 9.

FIG. 9 shows an ESD protection verification apparatus 2 according to the third embodiment of the present invention.

If high-voltage stress due to an ESD surge is applied across the source and drain of a MOS transistor (MOSFET), snapback may be caused in the MOS transistor. As a result, an ESD path may be produced between the source and the drain, and the MOS transistor may be destroyed by the ESD.

The snapback voltage in each MOS transistor is different, for example, depending on whether the MOS transistor is an N-channel type or a P-channel type, depending on whether the MOS transistor is designed for a high breakdown voltage or a low breakdown voltage, depending on the gate length of the MOS transistor, depending on the gate width of the MOS transistor, depending on the connection information for the gate of the MOS transistor, depending on the connection information for the bulk electrode of the MOS transistor, and depending on the number of contacts connected to each electrode.

The ESD protection verification apparatus 2 according to the third embodiment extracts a MOS transistor in design layout data, and determines that the MOS transistor may be destroyed by ESD if the intensity of the snapback voltage of the extracted MOS transistor is less than a reference value.

The specific configuration of the ESD protection verification apparatus 2 in the present embodiment is as follow:

As shown in FIG. 9, the ESD protection verification apparatus 2 according to the present embodiment comprises a pad selection unit 20 for selecting, for example, layout data for one pad among a plurality of pads including in the design layout data.

An FET extraction unit (element extraction unit) 21 in the ESD protection verification apparatus 2 extracts layout data for a MOS transistor connected to the selected pad from the design layout data. For example, the FET extraction unit 21 checks the connection information (first connection information) for the source and the connection information (second connection information) for the drain, and extracts a MOS transistor having its source and drain directly connected to different external pads. In addition, the MOS transistor extracted here not only includes a MOS transistor designed as a constituent element of a circuit but also includes a parasitic transistor. The parasitic transistor in the design layout data is extracted, for example, on the basis of information on a P-type impurity region (e.g., a P-type well region) and an N-type impurity region (e.g., an N-type well region) and on the basis of the connection information for the constituent elements.

An FET information checking unit (element information checking unit) 22 in the ESD protection verification apparatus 2 checks at least one of the kind of extracted MOS transistor, the gate length, the gate width, the connection information for the gate, and the connection information for the bulk electrode, out of a database stored in a storage device 3.

A snapback voltage processing unit (operating characteristics processing unit) 23 in the ESD protection verification apparatus 2 calculates, as an operating value, the snapback voltage of the extracted MOS transistor from the connection information checked by the connection information checking unit 22 and from a database for the snapback voltages of the MOS transistor in various design conditions (e.g., the gate length).

The database for the snapback voltages of the MOS transistor is created, for example, in accordance with a previously conducted simulation or experiment in the same manner as the element information for the diode and its ESD withstand voltage described in the first embodiment, and is stored in the storage device 3. The storage device 3 also stores the element information for the MOS transistor. In addition, the snapback voltages of the MOS transistor may be sequentially calculated by a calculating formula using the element information including the element number and dimension of the extracted MOS transistor without using the database.

An error detection unit 24 in the ESD protection verification apparatus 2 compares a certain reference value with the operating value calculated by the snapback voltage processing unit 23, referring to the database in the storage device 3. The error detection unit 24 detects, as an error, a MOS transistor whose calculated snapback voltage (operating value) is less than the reference value. The reference value is, for example, a value based on a value predicted from an ESD breakdown current or ESD surge caused in a pad. This reference value is found in the following manner: data based on the result of a previously conducted experiment or simulation is acquired from the storage device 3, or a value is simulated by an error detection unit 13 from the information for the selected pad.

A verification completion determination unit 25 is provided in the ESD protection verification apparatus 2. The verification completion determination unit 25 determines whether the verifications of all the MOS transistors that can be ESD paths are complete. If the verifications of all the MOS transistors are not complete, unverified MOS transistors present on the ESD path are repeatedly extracted, and their snapback voltages are verified.

Furthermore, for example, an error correction unit 26 is provided in the ESD protection verification apparatus 2. Once all the verifications are complete, the error correction unit 26 corrects data on, for example, the dimension and connection information of the MOS transistor so that the MOS transistor detected as an error satisfies a predetermined snapback voltage.

As described above, the ESD protection verification apparatus 2 according to the third embodiment of the present invention determines whether the snapback voltage of the MOS transistor calculated from the element information is greater than or equal to a required value. Thus, whether a MOS transistor that can be an ESD path satisfies the required ESD withstand voltage is verified.

The ESD protection verification apparatus 2 according to the present embodiment targets the MOS transistor for the ESD protection verification, and extracts a MOS transistor that can be an ESD path on the basis of the connection information for the pad and the source/drain. Then, the ESD protection verification apparatus 2 finds the snapback voltage of the extracted MOS transistor from the element information, and verifies the ESD withstand voltage in accordance with the intensity of the snapback voltage. If the MOS transistor does not ensure a predetermined snapback voltage, data on this MOS transistor is corrected. Thus, in a MOS transistor manufactured in accordance with the design layout data, a circuit including the MOS transistor can be prevented from being destroyed by ESD.

The ESD protection verification apparatus 2 according to the present embodiment checks the information on the connection between the pad and the source/drain, and thereby selectively extracts a MOS transistor for which no ESD breakdown measures are taken and which can cause a snapback. Thus, the MOS transistor is selectively extracted, so that the time required for the ESD protection verification is not significantly increased, and the speed of processing for the ESD protection verification of the design layout data is not much deteriorated.

Furthermore, the following techniques are generally used to prevent the ESD breakdown of the MOS transistor: a technique that adds a salicide block resistance to at least one of the drain and source of the MOS transistor, and a technique that cascodes the MOS transistors.

These techniques do not apply to the condition that the source and drain be directly connected to pads having different connection information. Thus, the MOS transistors to which these methods are applied are not extracted, and the MOS transistors for which these methods are implemented are not erroneously determined as not satisfying the reference of the snapback voltage.

Consequently, according to the ESD protection verification apparatus 2 in the third embodiment of the present invention, highly reliable ESD protection verification can be performed at high speed.

Although the snapback voltage is used to verify whether the MOS transistor satisfies a predetermined ESD withstand voltage in the present embodiment, the snapback voltage is not exclusively used and other properties may be used as long as such properties are the electrical properties of the MOS transistor correlated with the ESD withstand voltage.

(b) Operation

The ESD protection verification method according to the third embodiment of the present invention is described with reference to FIG. 10. In the present embodiment, the snapback voltage of the MOS transistor is used to verify the ESD withstand voltage of the MOS transistor that can be an ESD path.

FIG. 10 is a flowchart showing a processing flow of the ESD protection verification method according to the third embodiment of the present invention.

For example, as shown in FIG. 10, among a plurality of pads included in the input design layout data, one or two pads are selected by the pad selection unit 20 provided in the ESD protection verification apparatus 2 (step ST20). The selected pad is treated as a pad to serve as a base point of a verification target.

Then, one or more MOS transistors connected to the selected pad are selected by the FET extraction unit 21 provided in the ESD protection verification apparatus 2 (step ST21).

In this step, the extracted MOS transistor is a transistor in which its source and drain have different connection information and which is directly connected to the pad. Thus, the MOS transistor for which ESD breakdown measures are taken, for example, the MOS transistor to which the salicide block resistance is added or the MOS transistor which is cascoded does not satisfy the condition for connection to the pad and is not selected. Moreover, the MOS transistor extracted here may include a parasitic transistor. In addition, the MOS transistor is extracted using the pad as a reference here. However, after one MOS transistor is directly extracted from the design layout data, the connection to the pad may be checked.

Then, the element information and connection information for the extracted MOS transistor are checked by the FET information checking unit 22 (step ST22). The information on the transistor checked here is at least one of, for example, the kind of extracted MOS transistor, the gate length, the gate width, the connection information for the gate, and the connection information for the bulk electrode. The FET information checking unit 22 checks such information by using the data included in the design layout data or by combining the design layout data with the data in the storage device 3.

Furthermore, on the basis of the checked element information and connection information, the snapback voltage (operating value) of the extracted MOS transistor is acquired by the snapback voltage processing unit 23 (step ST23). The snapback voltage (operating value) may be acquired from a database which indicates the correspondence between the element information and the snapback voltage stored in the storage device 3 or may calculated by a calculation using the checked element information (e.g., the gate length or gate width).

Then, the acquired snapback voltage is compared with a certain reference value to find out whether this snapback voltage is greater than or equal to the reference value (step ST24-1). The reference value is acquired from, for example, a database. If the acquired snapback voltage is higher than the reference value, it is determined that the required ESD withstand voltage is satisfied.

On the other hand, if the acquired snapback voltage is less than or equal to the reference value, it is determined that the required ESD withstand voltage is not satisfied and ESD breakdown may occur. The MOS transistor whose snapback voltage is determined to be less than or equal to the reference value is checked as an error, and its coordinates (position) are stored in the storage device, or an error mark is added to the design layout data (step ST24-2). In addition, the reference value is set, for example, in accordance with a value obtained from a predicted value of an ESD breakdown current or ESD surge caused in the selected pad.

Then, whether the snapback voltages have been verified for all the extracted MOS transistors is determined by the verification completion determination unit 25 (step ST25).

If the verification is not complete, the flow from step ST20 to steps ST24-1 and ST24-2 is repeated.

When the verification is complete, data on the dimension and connection of the error MOS transistor, for example, is corrected by the error correction unit 26 (step ST26).

The ESD protection verification of the MOS transistor is completed by steps ST20 to ST26.

As described above, the ESD protection verification method according to the third embodiment of the present invention targets the MOS transistor for the ESD protection verification. Then, in the ESD protection verification method according to the present embodiment, whether the snapback voltage of the MOS transistor calculated by use of the element information is greater than or equal to the required value is determined. Thus, in the design layout data, whether the MOS transistor that can be an ESD path satisfies the required ESD withstand voltage is determined.

In the ESD protection verification method according to the present embodiment, a MOS transistor that can be an ESD path is extracted on the basis of the connection information for the pad and the source/drain, and the intensity of the snapback voltage of the extracted MOS transistor is used to verify the ESD withstand voltage of the transistor. If a predetermined snapback voltage is not ensured, the transistor may be destroyed by ESD, so that design data for this MOS transistor is corrected. Moreover, the transistor to be extracted also includes a parasitic transistor. This makes is possible to prevent the circuit including the parasitic transistor from being destroyed by ESD due to the application of the ESD breakdown current or ESD surge to the parasitic transistor without being reduced by other elements.

In the present embodiment, the information on the connection between the source/drain and the pad is checked to detect a MOS transistor for which no ESD breakdown measures are taken and which can cause a snapback.

Therefore, there is neither a significant increase in the time required for the ESD protection verification of the MOS transistor nor considerable deterioration in the speed of the ESD protection verification of the design layout data. Moreover, a MOS transistor for which the ESD breakdown measures are taken is not determined as not satisfying the required ESD withstand voltage for the reason that this MOS transistor does not satisfy a dimensional reference.

Consequently, according to the ESD protection verification method in the third embodiment of the present invention, highly reliable ESD protection verification can be performed at high speed.

### (4) Modification

A modification of the embodiments of the present invention is described using FIG. 11.

The ESD protection verification method described in the first to third embodiments can be applied to a program.

That is, the ESD protection verification apparatus described in the first to third embodiments may be a computer 5. For example, the computer 5 has a control unit 7A and a processing unit 7B. The ESD protection verification method shown in FIG. 4, 8 or 10 is written as a program. This program is stored in, for example, the control unit 7A in the computer 5 shown in FIG. 11. However, the program (software) may be provided by being stored in a storage unit (not shown) separately provided inside or outside the computer 5. Moreover, the program may be provided to the control unit 7A via a communication line such as the Internet.

Design layout data is input to the computer 5. The control unit 7A causes the processing unit 7B to execute the steps shown in one of FIGS. 4, 8 and 10 in accordance with the program.

As a result, the verification of the ESD withstand voltage that considers the parasitic diode or the verification of the ESD protection that considers the snapback voltage of the MOS transistor is performed for the design layout data input to the computer 5.

It goes without saying that effects similar to the effects provided by the ESD protection verification apparatus and the ESD protection verification method described in the first to third embodiments of the present invention can also be obtained if the program in which the ESD protection verification method is written is used as in the present modification.

Consequently, if the ESD protection verification method according to the embodiments of the present invention is applied to the program, highly reliable ESD protection verification can also be performed at high speed.

### (5) Addition

According to the first to third embodiments of the present invention, highly reliable ESD protection verification can be performed at high speed.

It goes without saying that the first to third embodiments of the present invention may be used in suitable combination instead of being separately used.

Although the diode and parasitic diode in the analog circuit are mainly targeted for the ESD protection verification in the cases described in the first to third embodiments of the present invention, it goes without saying that the diode in the logic circuit may also be included.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An ESD protection verification apparatus comprising:
an element extraction unit which extracts one or more elements connected to a first pad included in design data for a semiconductor integrated circuit;
a first element information checking/processing unit which checks connection information for the extracted element to determine one or more first connection information elements and which calculates a first operating value based on design information for the first connection information element, the first connection information element being configured so that a first electrode of the extracted element is connected to the first pad;
a first error detection unit which compares a first reference value with the first operating value to determine whether the first connection information element has a predetermined ESD withstand voltage;
a second element information checking/processing unit which checks connection information for the first connection information element to determine one or more second connection information elements and which calculates a second operating value based on design information for the second connection information element, the second connection information element being configured so that a second electrode of the first connection information element is connected to a second pad different from the first pad; and
a second error detection unit which compares a second reference value with the second operating value to determine whether the second connection information element has a predetermined ESD withstand voltage.

2. The ESD protection verification apparatus according to claim 1, further comprising:
an element group detection unit which checks the extracted element to find out whether the second electrode is connected to a pad other than the first pad, and detects an element connected to the second electrode when the second electrode is connected to no pad.

3. The ESD protection verification apparatus according to claim 1, further comprising:
an error correction unit which corrects the design information for the first or second connection information element not having the predetermined ESD withstand voltage when the first or second connection information element is determined not to have the predetermined ESD withstand voltage.

4. The ESD protection verification apparatus according to claim 1, further comprising:
a storage device which stores the design information and ESD withstand voltage information corresponding to the design information, wherein the design information indicates dimensions corresponding to a plurality of elements in the design data.

5. The ESD protection verification apparatus according to claim 1, wherein
the element extraction unit extracts a diode constituting a circuit, an ESD protection diode and a parasitic diode.

6. The ESD protection verification apparatus according to claim 5, wherein
the first operating value is a value based on at least one of the area, circumference, length and width of each of the diode, the ESD protection diode and the parasitic diode.

7. The ESD protection verification apparatus according to claim 1, wherein
when two or more first connection information elements are determined, the first element information checking/processing unit calculates the sum of the dimensions of the first connection information elements as the first operating value.

8. The ESD protection verification apparatus according to claim 1, wherein
when two or more second connection information elements are determined, the second element information checking/processing unit calculates the sum of the dimensions of the second connection information elements as the second operating value by using, as one unit, two or more second connection information elements connected to the same second pad.

9. An ESD protection verification apparatus comprising:
an element extraction unit which selects one first pad from a plurality of pads included in design data for a semiconductor integrated circuit and extracts an element connected to the selected first pad;
an element information examining unit which checks design information for the extracted element;
a processing unit which calculates an operating value indicating operating characteristics of the extracted element on the basis of the checked design information; and
an error detection unit which compares the operating value with a reference value and determines whether the extracted element has a predetermined ESD withstand voltage.

10. The ESD protection verification apparatus according to claim 9, further comprising:
an error correction unit which corrects the dimension of the element not having the predetermined ESD withstand voltage in the design data when the extracted element is determined not to have the predetermined ESD withstand voltage.

11. The ESD protection verification apparatus according to claim 9, further comprising:
a storage device which stores information on operating characteristics corresponding to a plurality of elements in the design data, and ESD withstand voltage information corresponding to the operating characteristics information.

12. The ESD protection verification apparatus according to claim 9, wherein
the extracted element is directly connected to the first pad.

13. The ESD protection verification apparatus according to claim 9, wherein
the element extraction unit extracts a field effect transistor and a parasitic transistor.

14. The ESD protection verification apparatus according to claim 9, wherein
the operating characteristics are a snapback voltage of a transistor.

15. An ESD protection verification method comprising:
extracting one or more elements connected to a first pad included in design data for a semiconductor integrated circuit;
checking connection information for the extracted element to determine one or more first connection information elements, and calculating a first operating value based on design information for the first connection information element, the first connection information element being configured so that a first electrode of the extracted element is connected to the first pad;
comparing a first reference value with the first operating value to determine whether the first connection information element has a predetermined ESD withstand voltage;
checking connection information for the first connection information element to determine one or more second connection information elements, and calculating a second operating value based on design information for the second connection information element, the second connection information element being configured so that a second electrode of the first connection information element is connected to a second pad different from the first pad; and
comparing a second reference value with the second operating value to determine whether the second connection information element has a predetermined ESD withstand voltage.

16. The ESD protection verification method according to claim 15, further comprising:
correcting the design data for the first or second connection information element not having the predetermined ESD withstand voltage when the first or second connection information element does not have the predetermined ESD withstand voltage.

17. The ESD protection verification method according to claim 15, further comprising:
determining whether the second electrode of the first connection information element is connected to a pad exclusive of the first pad or to an electrode of another element.

18. The ESD protection verification method according to claim 15, wherein
the extracted element is an ESD protection diode, a diode constituting a circuit, and a parasitic diode.

19. The ESD protection verification method according to claim 15, wherein
the extracted element is a field effect transistor and a parasitic transistor in which one end of a current path is directly connected to the first pad.

20. The ESD protection verification method according to claim 15, wherein
the design information indicates at least one of a dimension of the element and electrical properties of the element.
